(19) United States
(12) Patent Application Publication
(10) Pub. No.: US 2011/0094876 A1
(43) Pub. Date: Apr. 28, 2011

(54) Germanium-containing vacuum coating for noble-metal components

(76) Inventor: Yi-Hsiang Liang, Changhua City (TW)

(21) Appl. No.: 12/588,740

(22) Filed: Oct. 27, 2009

(51) Int. Cl. C23C 14/35

(52) U.S. Cl. 204/192.15

(57) ABSTRACT

The present invention relates to a method of germanium-containing vacuum electroplating for noble-metal components, whose steps comprising: (1) fabricating the components, (2) surface layer treatment, (3) germanium coating, (4) titanium coating, (5) gasification and (6) product assembly, whereby to amply reduce environmental pollution and to add germanium and titanium elements to noble metals, and to help enhancing user's health by the application of the physical characteristics of said germanium and titanium elements so as to increases the added-value to the noble-metal products and broaden the scope of their application.

### BACKGROUND OF THE INVENTION

1. Field of the Invention

The present invention relates to a method of germanium-containing vacuum coating for noble-metal components, particularly to a method of germanium-containing vacuum coating that is both environmental friendly and able to increase added values to products, whereby to bring about an effect of noble metals containing germanium and titanium after the process, also to increase the commercial values and application of these metals by virtue of the physical feature of the elements of germanium and titanium that enhances users' health.

2. Prior Art

The physical characteristic of the element germanium that it ionizes, insulates and neutralizes electro-magnetic waves, particularly throws off negative electrons at 32° C., has been used in medical field, as is already widely known, to help balancing the positive and negative electrons in human body so as to enhance human blood circulation. Hence there already are manufacturers of optical frame, necklace, bracelet and the like of noble-metal components who imbed germanium pellets (13) on the products (1) of those components (as shown in FIGS. 1 and 2) and make the products welcome in many areas for they help the wearers improving both their status and physical condition. Conventionally the said products (1) of noble-metal components with germanium pellets (13) imbedded used to be structured by providing on the component (11) of the product (1) a recess (12) to imbed (or adhere) said germanium pellet (13), in a fabricating method (2) (as shown in FIG. 3) consisting of the following steps:
(1) fabricating the component (Step 21), which cuts the metal wire using mold and die and forms it into the components (11) for a product (1) (e.g., a necklace, a bracelet and an optical frame);
(2) assembling (Step 22), which assembles the components (11) to one workpiece for further processing;
(3) installing the germanium pellets (Step 23), which imbeds the germanium pellets (13) in the recess (12) on the components (11) of said workpiece to achieve a finished product (1).

The conventional fabricating method mentioned above brings the effect of the germanium element to products; however, it has a drawback in terms of mass production in volume because the operation of imbedding requires a lot of labor, besides that germanium is expensive. In addition, the uneven distribution of germanium pellets is often criticized for affecting the effect of use. In such background, the author of the present invention proposed a “Method of fabricating ornaments” (as Taiwan patent application No. 95149751, China patent application No. 200710005684-4, hereinafter jointly referred to as the “Previous invention”), in which method the finished products can be produced at lower cost and in large volume; yet, though capable of effectively solving the drawbacks of heavily labor-demanding operation of imbedding germanium pellets and difficulty in massive production in conventional method, this previous invention is a method of electroplating using liquid (i.e., water), in which a huge volume of water is consumed with pollutions of waste water containing heavy metals like Cr, Ni, Zr, Sn and their alloys, and emission. Among these pollutions, hexavalent chromium and cyanides are extremely toxic and difficult to totally eliminate even by costly waste water treatment, while they tend to accumulate over time to a serious toxic hazard. Moreover, the attachment on product by electroplating in liquid (water) is not easy to control, causing the germanium distribution on product uneven at times, hence, a waste of expensive germanium as material.

As above stated, the drawback of environmental pollution by electroplating in liquid (water) is yet to be solved. And to solve it with techniques currently available, one has to resort to the method of electroplating of metals in vacuum, commonly known as plasma coating, or IP electroplating. Here is how it works: plasma is formed by inducing electric discharge in a vacuum coating machine to hit a metal target and make that metal element ionize and then deposit on the surface of a workpiece to form a film of inter-metal composite. Though such technique has been widely applied to the process of coating with any single metal (e.g., titanium) other than germanium, its application with germanium as material in noble-metal products remains a problem to be overcome due to the technical obstacle, yet to be vaulted, of making target of germanium, and the presence of uneven film from current IP electroplating as well as the inability to achieve multi-layer composite coating in one single process. Furthermore, in the trend of demanding products of noble-metal components made in various fashionable colors, the conventional IP electroplating is often unwelcome for it has provided only a limited range of basic colors.

### SUMMARY OF THE INVENTION

Accordingly, it is an object of the present invention to provide a method of germanium-containing vacuum electroplating for noble-metal components that is environmental friendly and increases added-value to the products, whose steps comprising: (i) fabricating the components, (ii) surface layer treatment, (iii) germanium coating, (iv) titanium coating, (v) gasification and (vi) product assembly, whereby to largely reduce environmental pollution during production and to bring about the germanium- and titanium-containing effect to noble metals after treatment, the physical property of which elements is used to enhance user's health while the change in luster made to the surface of the noble metals can effectively improve their added value and scope of application.

Of the method in the present invention mentioned above, said steps of germanium coating and titanium coating can achieve even coating by means of the spin of the holder(s) disposed inside a vacuum coating machine in combination with the rotation of a disc, with a multiple of targets disposed around the vacuum chamber of the vacuum coating machine to surround a workpiece from all directions, and can achieve multi-layer composite film coating in one single process by means of the disposition of targets of different materials (e.g., germanium target and titanium target), realizing the purpose of product surface with a titanium film on top of a germanium film.

Of the method in the present invention mentioned above, said steps of gasification further renders the titanium film in different colors on its surface by means of letting different kinds of gases in said vacuum coating machine, whereby to meet the market demand in regard of color. For example, the color of rosy gold can be achieved by adding nitrogen, sapphire by carbon dioxide, and gray by acetylene.

### BRIEF DESCRIPTION OF THE DRAWINGS

FIG. 1 is a perspective diagram of conventional noble-metal component.

FIG. 2 is a cross-sectional diagram of conventional noble-metal components.

FIG. 3 is the flowchart for fabrication of conventional noble-metal components.

FIG. 4 is a diagram showing the work of a vacuum coating machine in the present invention.

FIG. 5 is a 2-D diagram of a vacuum coating machine in the present invention.

FIG. 6 is a diagram showing the action in the plasma active zone in the present invention.

FIG. 7 is the flowchart of steps of the method in the present invention.

FIG. 8 is a cross-sectional diagram of the workpiece in the present invention.

FIG. 9 is a perspective diagram of an embodied product in the present invention.

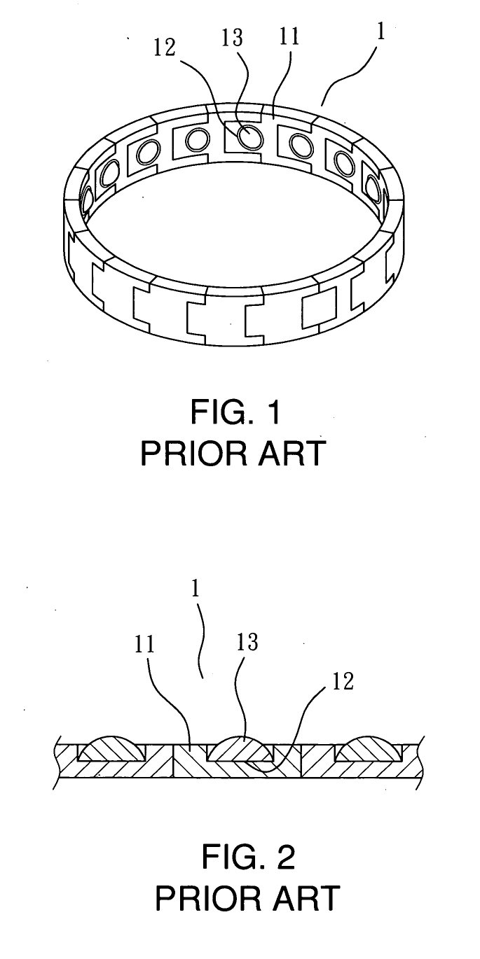

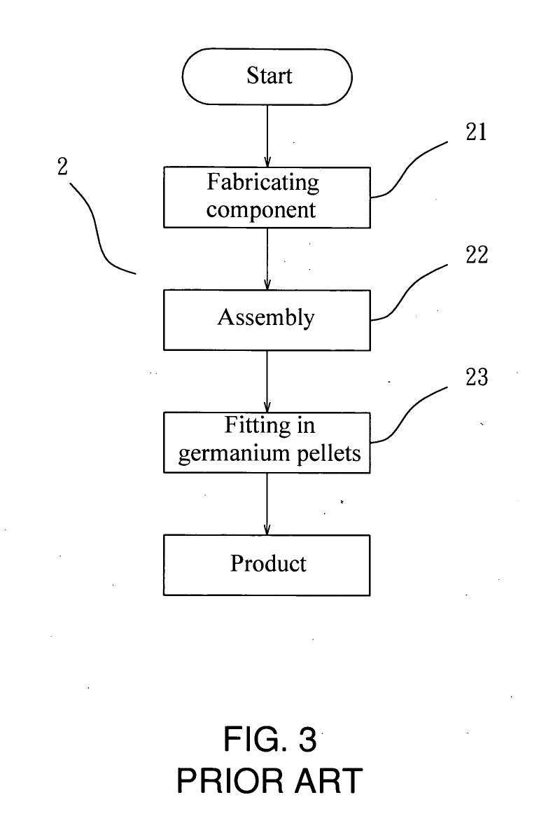

### DETAILED DESCRIPTION OF THE PREFERRED EMBODIMENTS

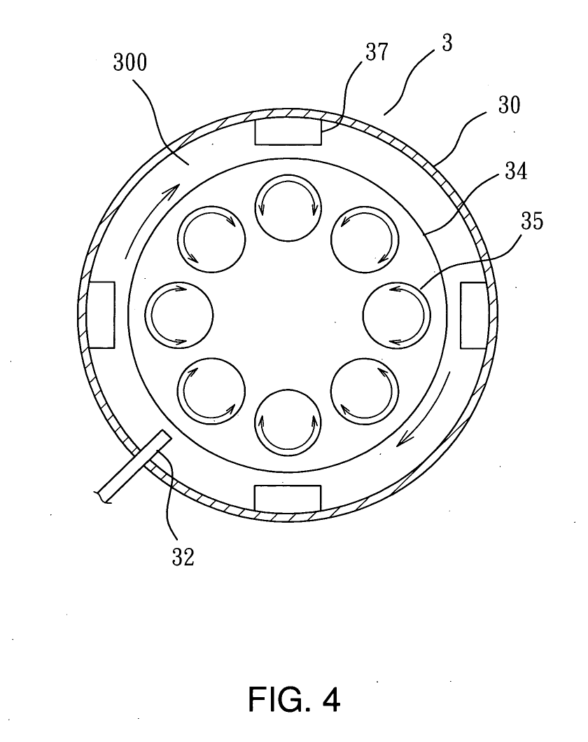

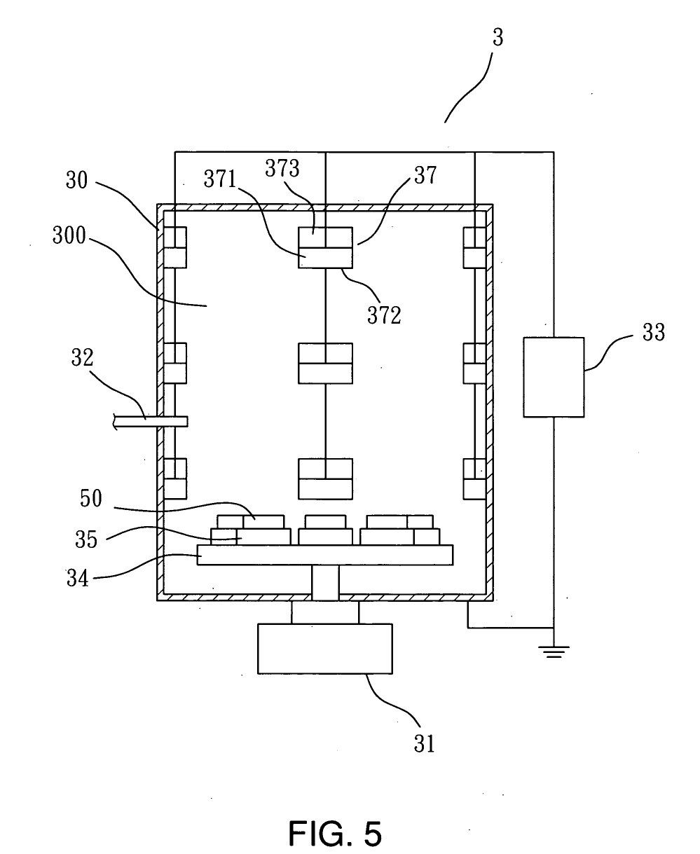

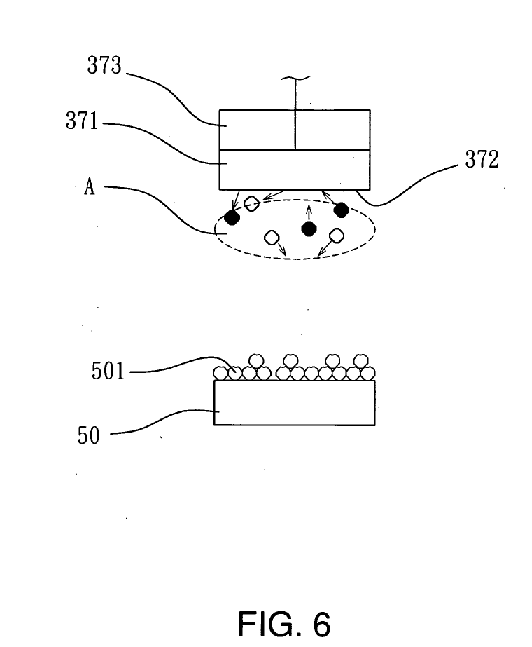

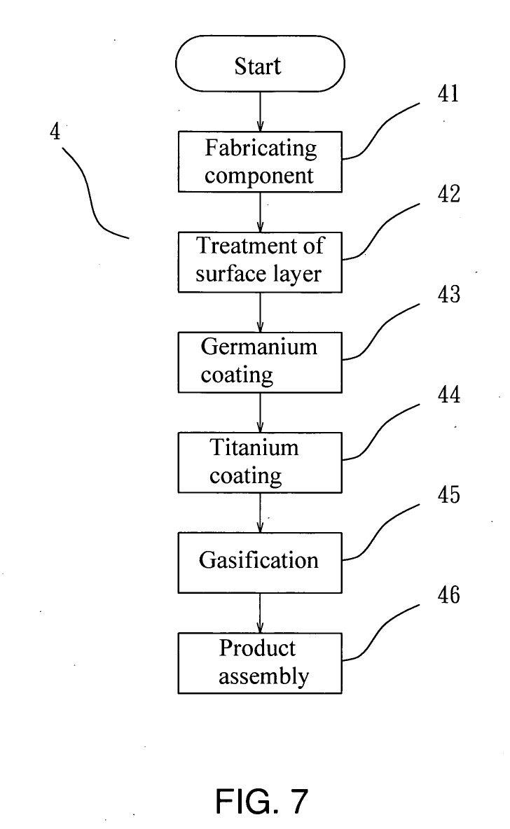

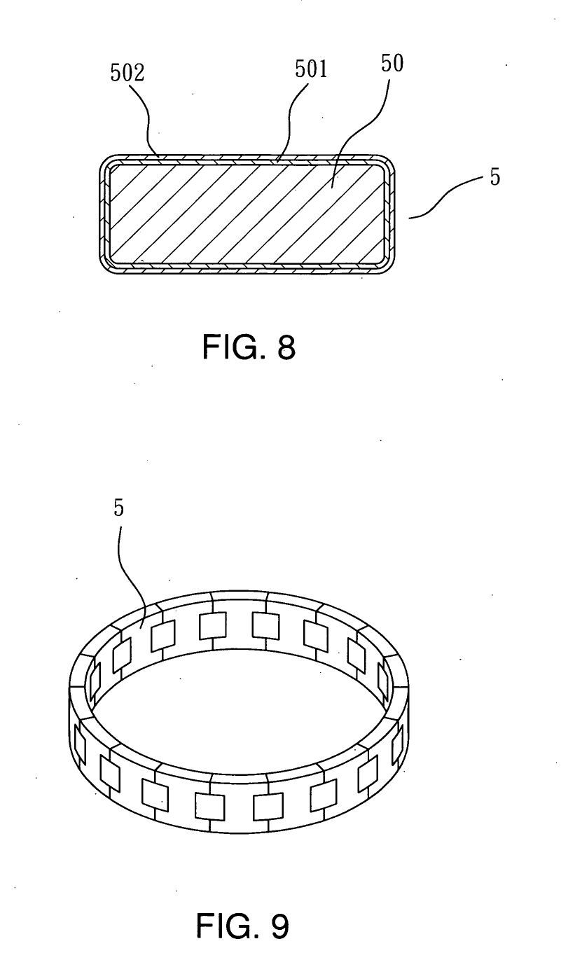

The present invention discloses a germanium-containing vacuum coating method (4) for noble-metal components (refer to FIGS. 4-7), which executes the steps of the method (4) of the present invention in a vacuum coating machine (3), wherein said vacuum coating machine (3) is provided in its housing (30) a vacuum chamber (300), and at its bottom a vacuum pump (31), and connected to said housing (30) is at least an inlet pipe (32) on the outside, provided on the peripheral of said vacuum chamber (300) are a plurality of target bases (37), each being structured by a magnet set (373) that consists of a permanent magnet and an electromagnet combined with a target (371) (said target can be of any metal material, such as germanium and titanium, depending on the desired film to coat), of which the targets (371) of different substances can be disposed around said vacuum chamber (300) in an evenly spaced manner, whereby a workpiece (50) is surrounded by plural targets of multiple materials in all direction. Also, in order to ensure every workpiece (50) has an even surface coating, said vacuum chamber (300) is provided at its bottom a disc (34), on which a plurality of holders (35) are disposed to hold the work piece (50), said holders (35) being driven to spin in clockwise or anticlockwise directions in a timely controlled manner while said disc (34) rotates, such that every workpiece (50), when put on the holder (35), would attain a multi-direction exposure for an all-around coating treatment, so as to obtain an even coated film. By means of afore-mentioned vacuum coating machine (3), the steps of the method (4) (as shown in FIG. 7) in the present invention comprises:
(i) fabricating the components (Step 41), which cuts the metal material using die and mold, and fabricated it to workpiece (50) (e.g., necklace, bracelet and optical frame component) for further process;
(ii) surface layer treatment (Step 42), in which the workpiece (50) is acid pickled and eliminated of grease to get rid of the unwanted impurity on it before being placed inside said vacuum coating machine (3);
(iii) germanium coating (Step 43), in which, with the workpiece (50) placed on the holder (35), the driving power unit (33) supplies electricity to the electromagnet (373) of the target base (37) that is attached by a germanium target and energizes it to create a magnetic field and electron interaction and creates a plasma active zone (A) (as shown in FIG. 6) inside the vacuum chamber (300), whereby, subject to the plasma action, the target (371) (referring to germanium target) sputters its element off its surface (372) and the sputtered element deposits on the surface of the workpiece (50) to form a film of germanium (501) (as shown in FIG. 8); as said holder (35) spins in forward and reverse directions periodically in combination with the rotation of the disc (34), the germanium film (501) can be coated on the surface of the workpiece (50) evenly.
(iv) titanium coating (Step 44), after the completion of germanium coating process, the driving power unit (33) supplies electricity to the electromagnet (373) of the target base (37) that is attached by a titanium target and energizes it to create a magnetic field as well as electron interaction and creates a plasma active zone (A) (as shown in FIG. 6) inside the vacuum chamber (300), whereby, subject to the plasma action, the target (referring to titanium target) sputters its element off its surface (372) and the sputtered element deposits on the surface of the germanium film (501) of the workpiece (50) to form a film of titanium (502) (as shown in FIG. 8);
(v) gasification (Step 45), in which, during the step of germanium coating (Step 43), a gas (e.g., argon) is emitted from at least one inlet pipe (32) and generates plasma after said magnet (373) is supplied with electricity, and then, during the step of titanium coating (Step 44), a different gas, chosen depending on the desired color to turn out on the workpiece (50), further is emitted from said inlet pipe (32) to react with the titanium film (502) and render the film in a different color (for example, nitrogen emitted through the inlet pipe (32) results in a rosy-golden titanium film, and, naturally, a gas added in different proportion results in a film in yet another color);
(vi) product assembly (Step 46), in which all pieces of workpiece (50) are assembled into a product (5) (as FIG. 9 shows).

What is claimed is:

1. A germanium-containing vacuum coating method for noble-metal components, comprising the following steps:
(1) fabricating the components, wherein a metal material is cut using die and mold, and fabricated to workpiece for further process;
(2) surface layer treatment, wherein the workpiece is acid pickled and grease-eliminated before being placed inside a vacuum coating machine;
(3) germanium coating, wherein the workpiece is placed on a holder, and a driving power unit supplies electricity to the electromagnet of the target base that is attached by a germanium target and energizes said magnet to create a plasma active zone, in which the germanium target sputters its element off its surface to deposit on the surface of the workpiece and form a film of germanium;
(4) titanium coating, wherein said driving power unit supplies electricity to the electromagnet of the target base that is attached by a titanium target and energizes said magnet to create a plasma active zone, in which the titanium target sputters its element off its surface to deposit on the surface of the workpiece and form a film of titanium;
(5) gasification, wherein gas(es) is/are emitted from at least one inlet pipe to generate plasma with said magnet being supplied with electricity during the steps of germanium coating and titanium coating;
(6) product assembly, wherein pieces of workpiece after completion of the coating processes are assembled as a product.

2. The germanium-containing vacuum coating method for noble-metal components in claim 1, wherein said step of gasification induces said titanium film to react and turn out in different surface colors by letting different gases in said vacuum coating machine.
